(19) United States
(12) Patent Application Publication
(10) Pub. No.: US 2021/0217652 A1
(43) Pub. Date: Jul. 15, 2021

(54) SEMICONDUCTOR STRUCTURE AND METHOD OF FORMING THEREOF

(71) Applicant: XIA TAI XIN SEMICONDUCTOR (QING DAO) LTD., Qingdao (CN)

(72) Inventors: CHANG-HYEON NAM, Singapore (SG); INJOON YEO, Singapore (SG)

(21) Appl. No.: 16/740,483

(22) Filed: Jan. 12, 2020

(51) Int. Cl. H01L 21/764; H01L 27/088; H01L 23/528; H01L 23/532; H01L 21/762; H01L 21/8234; H01L 21/768

(52) U.S. Cl. CPC H01L 21/764; H01L 27/088; H01L 23/528; H01L 23/53295; H01L 21/31116; H01L 21/823475; H01L 21/76834; H01L 21/823481; H01L 21/76224

(57) ABSTRACT

A semiconductor structure is disclosed. The semiconductor structure has a substrate, a signal line structure disposed on the substrate, a spacer disposed on the substrate, and an airgap disposed between the signal line structure and the spacer. The air gap has a upper region and a lower region below the upper region. The width of the upper region is different from the width of the lower region.

### BACKGROUND

### 1. Field

The present disclosure generally relates to semiconductor structure, and more particularly, semiconductor structure having air gap.

### 2. Description of the Related Art

When a highly integrated semiconductor structure is manufactured, a parasitic capacitance is generated between adjacent layers. Thus, the performance and reliability of the semiconductor structure is degraded. To reduce the parasitic capacitance component, low-K material or equivalent (e.g., air gap) may be interposed between the adjacent layers to effectively further reduce the parasitic capacitance between the adjacent layers. However, generating a structure with embedded air gap sometimes presents a challenge. For one thing, a previously generated void in a semiconductor structure may be inadvertently filled in a subsequent deposition process, thus spoiling previous void generating efforts.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flowchart of a method of forming a semiconductor structure according to some embodiments of the instant disclosure;

FIG. 2A-2H illustrate a cross sectional views of a semiconductor structure according to some embodiments of the instant disclosure;

FIG. 3 illustrates a cross sectional views of a semiconductor structure according to some embodiments of the instant disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

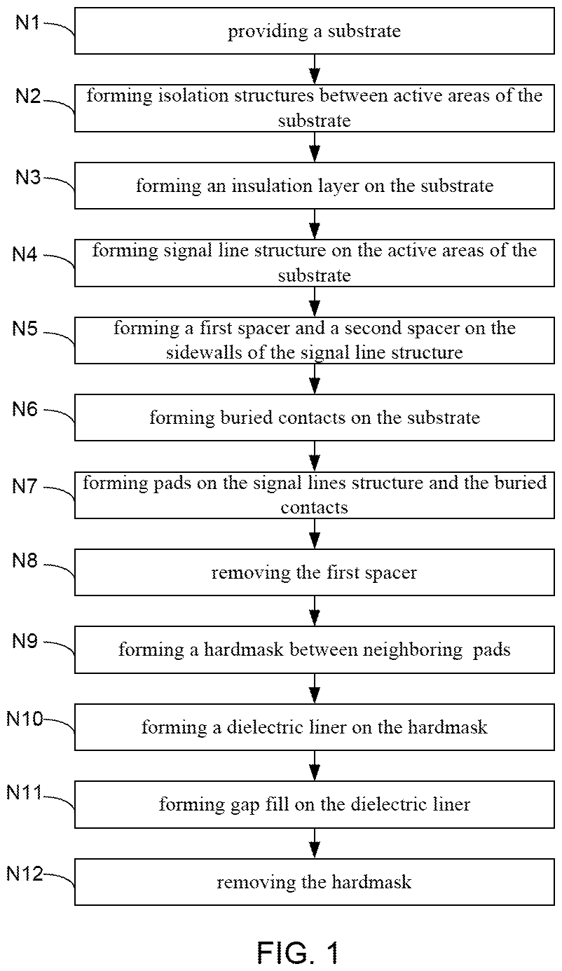

FIG. 1 illustrates a flowchart of a method of forming a semiconductor structure according to some embodiments of the instant disclosure. The method includes providing a substrate (N1), forming isolation structures between active areas of the substrate (N2), forming an insulation layer on the substrate (N3), forming signal line structure on the active areas of the substrate (N4), forming a first spacer and a second spacer on the sidewalls of the signal line structure (N5), forming buried contacts on the substrate (N6), forming pads on the signal lines structure and the buried contacts (N7), removing the first spacer (N8), forming a sacrificial filler between neighboring pads (N9), forming a cap liner on the sacrificial filler (N10), forming gap fill on the cap liner (N11), and removing the sacrificial filler (N12).

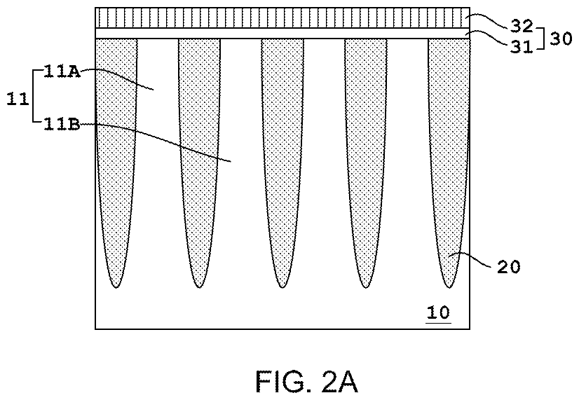

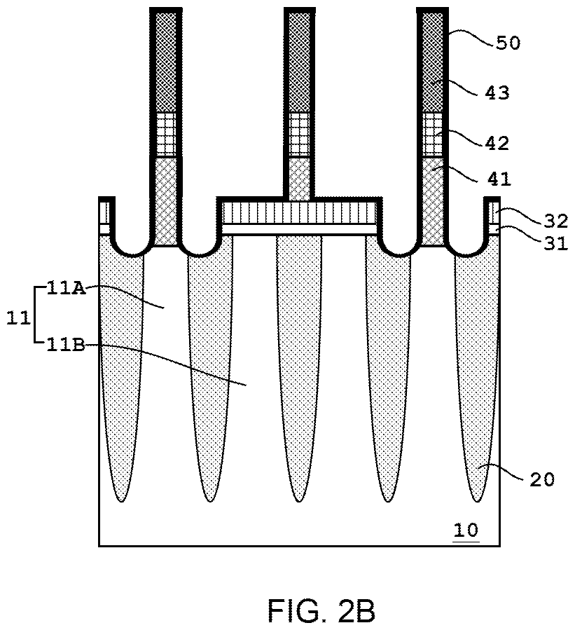

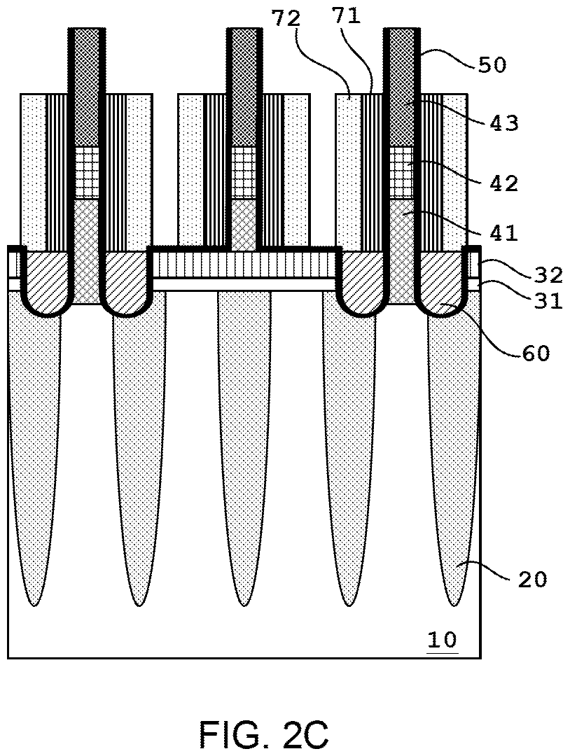

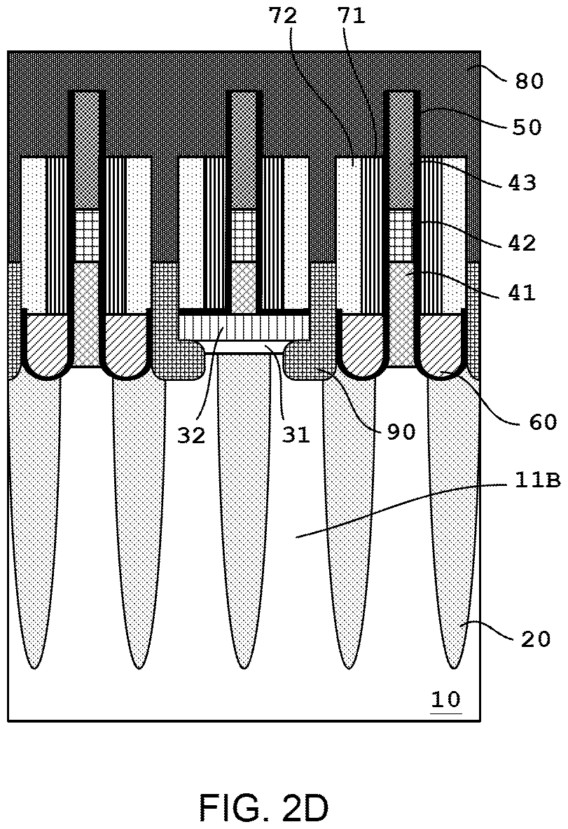

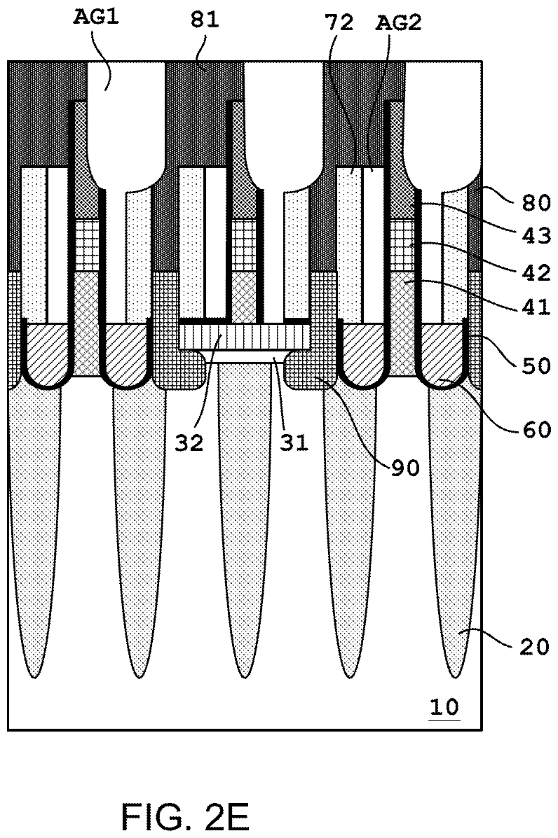

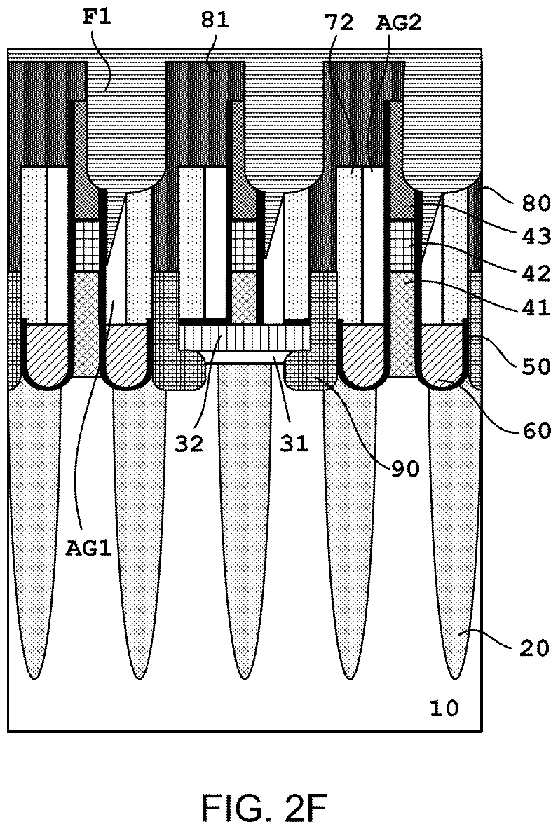

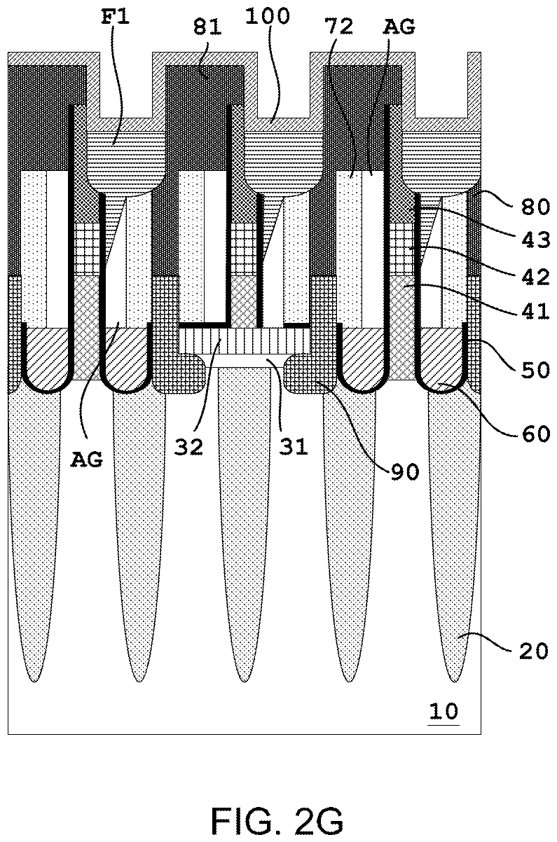

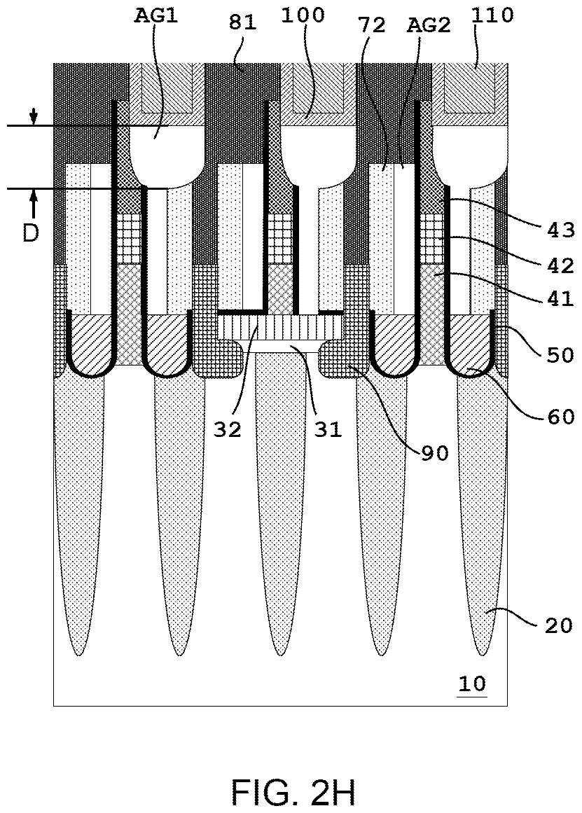

FIGS. 2A-2H illustrate cross-sectional views of a semiconductor structure according to some embodiments of the instant disclosure. Each of FIGS. 2A-2H illustrates a process of the method described in FIG. 1 according to some embodiments of the instant disclosure.

As shown in FIG. 2A, an isolation structure 20 is formed in a substrate 10. An area of the substrate 10 between neighboring isolation structures 20 define a plurality of active areas 11 including a first active area 11A and a second active area 11B. In some embodiments, the substrate 10 includes a semiconductor material such as germanium (Ge), silicon carbide (SiC), gallium arsenide (GaAs), indium arsenide (InAs), and indium phosphide (InP). In some embodiments, the substrate 10 includes a doped well or a doped region.

In some embodiments, the isolation structure 20 is a buried oxide layer (BOX) layer or a shallow trench isolation (STI) structure. In some embodiments, the isolation structure 20 includes at least one of an oxide layer and a nitride layer. In some embodiments, the isolation structure 20 is formed of a single layer of one type of insulation material or a multilayer of different types of insulation material.

An insulation layer 30 may be formed on an active surface of the substrate 10. In some embodiments, the insulation layer 30 includes at least one of an oxide layer 31 and a nitride layer 32 (e.g., silicon nitride, SiN). In some embodiments, the oxide layer 31 and the nitride layer 32 are sequentially stacked.

As shown in FIG. 2B, a signal line structure comprising a first conductive portion 41, a second conductive portion 42, and a capping portion 43 is formed the active surface of over the substrate 10. In some embodiments, the signal line structure is a bit line structure.

To form the signal line structure, a contact hole (e.g., blind hole h) is formed through the insulation layer 30 and a portion of the substrate 10 to exposes a portion of a corresponding first active area 11A. A first conductive layer (e.g., pre-patterned layer 41), a second conductive layer (e.g., pre-patterned layer 42), and a capping layer (e.g., pre-patterned layer 43) are sequentially disposed over the active surface of the substrate 10. In some embodiments, the first conductive layer formed above the contact hole is thicker than the first conductive layer formed above the insulation layer 30. However, in some embodiments, the top surface of the first conductive layer is substantially planar. Afterwards, the first conductive layer, the second conductive layer, and a capping layer are patterned to form the first conductive portion 41, the second conductive portion 42, and a capping portion 43, respectively. In some embodiments, the first conductive portion 41 disposed above the first active area 11A is electrically coupled to the first active area 11A. In some embodiments, the first conductive portion 41 disposed above the insulation layer 30 is electrically isolated form the second active area 11B. In some embodiments, the second conductive portion 42 is a unitary layer substantially made from a same material. In some other embodiments, the second conductive portion 42 includes a plurality of layers of different materials stacked on top of each other.

In some embodiments, a material of the first conductive portion 41 includes at least one of silicon, doped polysilicon, and metal. A material second conductive portion 42 includes at least one of titanium nitride (TiN), titanium silicon nitride (TiSiN), tungsten (W), and tungsten silicide. A material of the capping portion 43 includes Silicon Nitride (SiN).

After forming the signal line structure, an insulation liner 50 is formed over the signal line structure, the insulation layer 30, the isolation structure 20, and the substrate 10 in a conformal manner. In some embodiments, sidewalls of the signal line structure are covered by the insulation liner 50. In some embodiments, during the etching process forming the signal line structure, a portion of the first active area 11A (e.g., an edge portion) and the isolation structures 20 proximate the first active area 11A are further removed, whereby a portion of the insulation liner 50 forms a bottom surface (at the removed region) lower than the bottom surface of the first conductive portion 41 disposed over the first active area 11A. Accordingly, the insulation liner 50 at the root region of the signal line structure above the first active area 11A forms a recessed area.

As shown in FIG. 2C, the recessed area of the insulation liner 50 is filled with filler 60. The material for the filler 60 includes Silicon Nitride (SiN). In some embodiments, the top surface of the filler is substantially co-planar with the top surface of the insulation layer 30.

Afterwards, a first spacer 71 and a second spacer 72 are sequentially formed on the sidewalls of the signal line structure. The spacer formation process may include: disposing a first insulation layer over the signal line structure and the insulation liner 50. A portion of the first insulation layer is then removed (e.g., the horizontally covering portion, removed using anisotropic etching techniques) to form the first spacer 71. Subsequently, a second insulation layer is disposed over the signal line structure and the first spacer 71. A portion of the second insulation layer is removed to form the second spacer 72 in a comparable fashion (e.g., through anisotropic etch).

In some embodiments, the material for the first spacer 71 includes at least one of a silicon oxide and a silicon nitride. And, the material for the second spacer 72 includes at least one of a silicon oxide layer and a silicon nitride layer. In some embodiments, the first spacer 71 and the second spacer 72 have substantially the same height. In some embodiments, the first spacer 71 and the second spacer 72 have different height. In some embodiments, the first spacer 71 and the second spacer 72 have substantially the same height as the signal line structure.

In some embodiments, some of the first spacers 71 and some of the second spacers 72 are disposed over the filler 60. In some embodiments, a plurality of the first spacers 71 and all of the second spacers 72 are correspondingly formed at the same elevation defined over the substrate 10 (e.g., on a plane cooperatively defined by the top boundary of the filler 60 and the insulation layer 30).

As shown in FIG. 2D, a plurality of buried contacts 90 are formed in spaces between the respective plurality of signal line structure. In some embodiments, during the contact formation process, a portion of the nitride layer 32 exposed between neighboring second spacers 72 to form a hole. Afterwards, in a different process, a portion of the isolation structure 20 and the oxide layer 31 exposed by the hole on the nitride layer 32 is removed. In some embodiments, a portion of the oxide layer 31 underneath the remaining nitride layer 32 and over the second active area 11B is removed. In some embodiments, the isolation structure 20 neighboring the second active area 11B is reduced in height. After removing a portion of the isolation structure 20 and the oxide layer 31, a portion of the second active area 11B exposed between the oxide layer 31 and the neighboring isolation structure 20 is removed. A conductive material is deposited within the formed recessed area to form the buried contact 90. In some embodiments, the buried contact 90 is formed to have a boot shape lateral cross section profile (as illustrated in FIG. 2D). In some embodiments, the bottom region of the buried contact 90 is wider than the top region of the buried contact 90. The material for the buried contacts 90 includes at least one of silicon, doped polysilicon, and metal.

A conductive layer 80 is formed over the substrate 10. In some embodiments, the conductive layer 80 is formed over the signal line structure, the first spacer 71, the second spacer 72, and the plurality of buried contacts 90 and substantially filling the gaps between the abovementioned structural features. A material second conductive layer 80 includes at least one of titanium nitride (TiN), titanium silicon nitride (TiSiN), tungsten (W), and tungsten silicide.

In some embodiments, a barrier layer (not shown) is formed over the conductive layer 80. The barrier layer may be formed by one or more layers including at least one of titanium and a titanium nitride.

As shown in FIG. 2E, a patterned mask (not shown) is disposed over the substrate 10 and is used to form a pad 81 by removing portions of the conductive layer 80. In some embodiments, the pad 81 are electrically coupled to the buried contact 90. When the portions of the conductive layer 80 are removed, top surface of corresponding first spacers 71 are exposed.

Afterwards, an etching operation is performed to remove at least a portion of the plurality of first spacers 71. In some embodiments, the etching operation comprises an oxide etching process. In some embodiments, substantially all of the plurality of first spacers 71 are removed. In some embodiments, residues of the plurality of first spacers 71 remains on the substrate 10. In some embodiments, a first air gap AG1 and a second air gap AG2 are formed in place of the first spacers 71.

It is to be noted that, the term “air gap” generally refers to the absence of material filling in a particular region (thereby forming a structure with void), and does not necessarily imply the gaseous content therein. In some embodiments, the voids between device features may be substantially filled with one or more inert gas such as gaseous argon or nitrogen. In some embodiments, the voids (air gaps) between the structural features may be substantially vacuum.

The etching operation is performed by supplying a cleaning gas that chemically reacts with and remove the first spacer 71. In some embodiments, the cleaning gas includes at least one of NH3, HF, H2, NF3, and IPA (isopropyl alcohol). The cleaning gas includes is selected according to the material used to form the first spacer 71. In some embodiments, the cleaning gas may be a plasma-less gas. In some embodiments, the cleaning gas further include an inert gas such as N2 or Ar. In using oxide etching process to remove the first spacer 71, galvanic corrosion is prevented. Thus, damage that may occur to the pad 81 is substantially reduced.

A purge operation may be performed to remove a remaining gas of the cleaning gas and a byproduct of the oxide etching operation. The byproduct may, for example, be (NH4)2SiF6. In some embodiments, the purge operation is performed at a high temperature of about 100° C. to about 300° C. In some embodiments, the purge operation is performed at a high vacuum degree of 0.000001 atm to 0.3 atm. In this way, sublimation of the byproduct is facilitated.

As shown in FIG. 2F, a sacrificial filler F1 is formed in the first air gap AG1. In some embodiments, the sacrificial filler F1 is a carbon-based material. In some embodiments, the sacrificial filler F1 contains about 60% carbon. The carbon-based material may easily be removed by plasma. In some embodiments, the carbon-based material for the sacrificial layer 213 includes at least one of a Spin-On-Carbon (SOC) layer, a photoresist (PR) layer, or a carbon layer for a hard mask. In an exemplary embodiment, the sacrificial filler F1 is a spin on hardmask. In an exemplary embodiment, the sacrificial filler F1 is an amorphous-liquid-crystalline (ALC) layer.

As shown in FIG. 2G, the sacrificial filler F1 is partially removed to form recessed areas. An etch back process may be utilized to partially remove the sacrificial filler F1. In some embodiments, the top surface of the sacrificial filler F1 is planar after the etch back process. The top surface of the sacrificial filler F1 is at a distance from a top surface of the pad 81.

Furthermore, a cap liner 100 is formed over the sacrificial filler F1 and the pad 81. In some embodiments, the cap liner 100 further disposed on sidewall of the pad 81 and sidewall of the capping portion 43.

In some embodiments, a material of the cap liner 100 includes a non-porous material, such as SiO2, SiN, SiON, or SiCN. In some embodiments, a thickness of the cap liner 100 ranges from about 20 Å to about 200 Å. In some embodiments, a thickness of the cap liner 100 ranges from about 5 Å to about 50 Å.

In some embodiments, to form the cap liner 100, an atomic layer deposition (ALD) method is used. The ALD method is implemented at a low temperature (e.g., about 50° C. to about 100° C.) to prevent the sacrificial filler F1 from being damaged or partially removed.

As shown in FIG. 2H, after the formation of the cap liner 100, access to the previously generated air gap (e.g., AG1/2) may be temporarily denied. As such, the general profile of the air gap may be retained despite of subsequent fabrication processes (e.g., deposition of further material layers, such as filler 110). Upon the formation of the cap liner 100, the remaining sacrificial filler F1 is substantially may be removed without affecting the general shape of the air gap (e.g., AG1/2). For instance, the sacrificial filler F1 underneath the cap liner 100 may be removed without damaging the cap liner 100. In some embodiments, the cap liner 100 forms recessed areas.

In some embodiments, plasma is used to remove the sacrificial filler F1. The method of removing the sacrificial filler F1 includes generating a plasma inside a process chamber where the substrate 10 is disposed. In some embodiments, the plasma includes at least one of oxygen, nitrogen, and hydrogen plasma. In an exemplary embodiment, when an oxygen plasma is generated, oxygen radicals are generated from the oxygen plasma passes through the cap liner 100 to reach the sacrificial filler F1. Then, the oxygen radicals and the carbon within the sacrificial filler F1 react with each other and changes the sacrificial filler F1 into CH4, N2, CO2, or CO radical. Afterwards, the CH4, N2, CO2, or CO radical passes through from the bottom surface of the cap liner 100 to be discharged out of the semiconductor structure. In this way, the sacrificial filler F1 under the cap liner 100 is removed to form the final shape of the first air gap AG1. In some embodiments, the removal of sacrificial filler F1 may be achieved through a thermal process. For instance, the carbon-heavy composition of the sacrificial filler F1 allows it to evaporate through the cap liner 100 at a relatively low temperature. In some embodiments, a heating process is performed at temperature up to 150° C. to facilitate removal of the filler material.

In some embodiments, the sectional shape of the first air gap AG1 is a funnel shape. The first air gap AG1 has a upper region and a lower region. The upper region of has a width greater than the lower region. The upper region is disposed between the bottom surface of the cap liner 100 and the first spacer 71. A height D is the distance the bottom surface of the cap liner 100 and the first spacer 71. In some embodiments, the height D is less than 20 nm. In some embodiments, the height D is about 20 nm. In some embodiments, a height of the lower region of the first air gap AG1 is about 800 Å. In some embodiments, a height of the lower region of the first air gap AG1 is greater than 800 Å. In some embodiments, a total height of the first air gap AG1 is greater than 800 Å. In some embodiments, a height of the lower region of the first air gap AG1 is less than a height of the second air gap AG2. In some embodiments, a height of the lower region of the second air gap AG2 is about 800 Å. In some embodiments, a height of the lower region of the second air gap AG2 is greater than 800 Å.

A gap fill 110 is formed within the recessed areas formed by the cap liner 100. A planarization process (e.g., chemical-mechanical polishing) may be performed upon the deposition of the gap fill material (e.g., filler 110). Accordingly, the upper most surface of the gap fill 110 may be substantially planar to a surface of the cap liner 100.

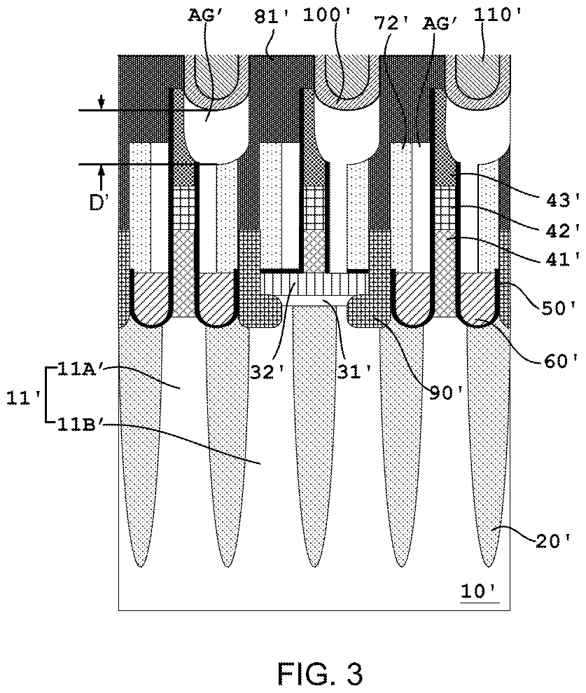

FIG. 3 illustrates a cross sectional views of a semiconductor structure according to some embodiments of the instant disclosure. The semiconductor structure includes a substrate 10′ having a plurality of active areas 11′, isolation structures 20′ disposed between neighboring active areas 11′, an insulation layer (31′/32′) disposed on the substrate 10′, a signal line structure (41′/42′/43′) disposed over the active areas 11′ of the substrate 10′, the insulation liner 50′ conformally formed on the substrate 10′ and the signal line structure, a filler 60′ disposed on the insulation liner 50′, spacers 72′ disposed above the insulation liner 50′, a buried contact 90′ disposed between neighboring spacers 72′, a pad 81′ disposed on the buried contact 90′, a cap liner 100′ on the pad 81′, and a gap fill 110′ disposed on the cap liner 100′.

In some embodiments, the insulation layer includes at least one of an oxide layer 31′ and a nitride layer 32′. In some embodiments, the signal line structure includes a first conductive portion 41′, a second conductive portion 42′, and a capping portion 43′. In some embodiments, the buried contact 90′ form a boot shape that extends underneath the top surface of the insulation layer. In some embodiments, the buried contact 90′ extends underneath and is in contact with the nitride layer 32′.

In some embodiments, a first air gap AG1′ is formed within the semiconductor structure. A first portion of the first air gap AG1′ is formed between a spacer 72′ and a signal line structure. A second portion of the first air gap AG1′ is formed between the pad 81′ and the signal line structure. In some embodiments, the second portion of the first air gap AG1′ is disposed above the spacer 72′. In some embodiments, the height D′ of the second portion of the first air gap AG1′ is less than 20 nm. In some embodiments, the height D′ of the second portion of the first air gap AG1′ is about 20 nm.

When forming the sectional shape of the first air gap AG1′, a sacrificial filler is formed in the first air gap AG1′. In some embodiments, the top surface of the sacrificial filler is curved. When the cap liner 100′ is formed, the cap liner 100′ conforms to the shape formed by the sacrificial filler and the pad 81′. In some embodiments, a thickness of the cap liner 100′ ranges from about 20 Å to about 200 Å. After forming the cap liner 100′, the sacrificial filler is substantially removed from the final structure of the semiconductor structure.

In some embodiments, the sectional shape of the first air gap AG1′ is a funnel shape. The first air gap AG1′ has a upper region and a lower region. The upper region has a width greater than the lower region. In some embodiments, second air gaps AG2′ is formed underneath the pad 81′. In some embodiments, the lower region of the first air gap AG1′ has a height less than the height of the second air gap AG2′.

Accordingly, one aspect of the instant disclosure provides a semiconductor structure that comprises a substrate having a plurality of active areas; isolation structures disposed between neighboring pair of the active areas; an insulation layer disposed over the isolation structure between neighboring pair of the active areas; a signal line structure disposed on active areas of the substrate; the insulation liner conformally formed on sidewalls of the signal line structure; spacers disposed over the insulation liner and respectively on lateral sides of the signal line structure; a buried contact and a pad disposed between neighboring spacers; and a cap liner over a respective one of the spacers, in contact with a lateral surface of the pad. An air gap is formed between the signal line structure and one of the spacers. And, the air gap has a sectional shape of a funnel shape.

In some embodiments, a portion of the buried contact is formed underneath the insulation layer.

In some embodiments, a sectional shape of the buried contact is a boot shape.

In some embodiments, the air gap has a upper region and a lower region, the upper region having a width greater than a lower region.

In some embodiments, a height of the upper region is less than 20 nm.

In some embodiments, a thickness of the cap liner ranges from about 20 Å to about 200 Å.

In some embodiments, a bottom surface of the cap liner is a planar surface.

In some embodiments, a bottom surface of the cap liner is a curved surface.

In some embodiments, the insulation layer has an oxide layer and a nitride layer.

In some embodiments, the structure further comprises a filler disposed between the spacer and the insulation liner, the filler having a top surface planar to a top surface of the insulation layer.

Accordingly, another aspect of the instant disclosure provides a method of forming a semiconductor structure that comprises providing a substrate having active areas; forming isolation structures between the active areas; forming an insulation layer on the substrate; forming signal line structure on the active areas of the substrate; forming a first spacer and a second spacer on sidewalls of the signal line structure; forming buried contacts in contact with one of the active areas over the substrate; forming pads on the signal line structures and the buried contacts; removing the first spacer; forming a sacrificial filler between neighboring pads; forming a cap liner on the sacrificial filler; and removing the sacrificial filler to form an air gap, the airgap having a funnel shape.

In some embodiments, the air gap has a upper region and a lower region, the upper region having a width greater than a lower region.

In some embodiments, a height of the upper region is less than 20 nm.

In some embodiments, a thickness of the cap liner ranges from about 20 Å to about 200 Å.

In some embodiments, the sacrificial filler is a carbon-based material.

In some embodiments, a top surface of the sacrificial filler is a planar surface and a bottom surface of the cap liner conforms to the top surface of the sacrificial filler.

In some embodiments, a top surface of the sacrificial filler is a curved surface and a bottom surface of the cap liner conforms to the top surface of the sacrificial filler.

In some embodiments, the insulation layer has an oxide layer and a nitride layer.

In some embodiments, forming the buried contacts on the substrate comprises removing a portion of the nitride layer of the insulation layer between neighboring second spacers to form a hole on the nitride layer; removing a portion of the oxide layer of the insulation layer and a portion of the isolation structure exposed through the hole on the nitride layer; and depositing a conductive material within a recessed area formed by the nitride layer, the oxide layer, and the isolation structure.

In some embodiments, a sectional shape of the buried contact is a boot shape.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having a plurality of active areas;
isolation structures disposed between neighboring pair of the active areas;
an insulation layer disposed over the isolation structure between neighboring pair of the active areas;
a signal line structure disposed on active areas of the substrate;
the insulation liner conformally formed on sidewalls of the signal line structure;
spacers disposed over the insulation liner and respectively on lateral sides of the signal line structure;
a buried contact and a pad disposed between neighboring spacers; and
a cap liner over a respective one of the spacers, in contact with a lateral surface of the pad;
wherein an air gap is formed between the signal line structure and one of the spacers, wherein the air gap has a sectional shape of a funnel shape.

2. The structure of claim 1, wherein a portion of the buried contact is formed underneath the insulation layer.

3. The structure of claim 1, wherein a sectional shape of the buried contact is a boot shape.

4. The structure of claim 1, wherein the air gap has a upper region and a lower region, the upper region having a width greater than a lower region.

5. The structure of claim 4, wherein a height of the upper region is less than 20 nm.

6. The structure of claim 1, wherein a thickness of the cap liner ranges from about 20 Å to about 200 Å.

7. The structure of claim 1, wherein a bottom surface of the cap liner is a planar surface.

8. The structure of claim 1, wherein a bottom surface of the cap liner is a curved surface.

9. The structure of claim 1, wherein the insulation layer comprises an oxide layer and a nitride layer.

10. The structure of claim 1, further comprises:
a filler (60) disposed between the spacer and the insulation liner, the filler having a top surface planar to a top surface of the insulation layer.

11. A method of forming a semiconductor structure, comprising:
providing a substrate having active areas;
forming isolation structures between the active areas;
forming an insulation layer on the substrate;
forming signal line structure on the active areas of the substrate;
forming a first spacer and a second spacer on sidewalls of the signal line structure;
forming buried contacts in contact with one of the active areas over the substrate;
forming pads on the signal line structures and the buried contacts;
removing the first spacer;
forming a sacrificial filler between neighboring pads;
forming a cap liner on the sacrificial filler; and
removing the sacrificial filler to form an air gap, the airgap having a funnel shape.

12. The method of claim 11, wherein the air gap has a upper region and a lower region, the upper region having a width greater than a lower region.

13. The method of claim 12, wherein a height of the upper region is less than 20 nm.

14. The method of claim 11, wherein a thickness of the cap liner ranges from about 20 Å to about 200 Å.

15. The method of claim 11, wherein the sacrificial filler includes a carbon-based material.

16. The structure of claim 11, wherein a top surface of the sacrificial filler is a substantially planar surface and a bottom surface of the cap liner conforms to the top surface of the sacrificial filler.

17. The structure of claim 11, wherein a top surface of the sacrificial filler is a substantially curved surface and a bottom surface of the cap liner conforms to the top surface of the sacrificial filler.

18. The structure of claim 11, wherein the insulation layer comprises an oxide layer and a nitride layer.

19. The structure of claim 18, wherein forming the buried contacts on the substrate comprises:
removing a portion of the nitride layer of the insulation layer between neighboring second spacers to form a hole on the nitride layer;
removing a portion of the oxide layer of the insulation layer and a portion of the isolation structure exposed through the hole on the nitride layer; and
depositing a conductive material within a recessed area formed by the nitride layer, the oxide layer, and the isolation structure.

20. The structure of claim 11, wherein a sectional shape of the buried contact is a boot shape.
